(19) United States
(12) Patent Application Publication
(10) Pub. No.: US 2013/0141341 A1
(43) Pub. Date: Jun. 6, 2013

(54) HANDHELD ELECTRONIC DEVICE

(71) Applicants: Yuan-Sheng Cheng, Taoyuan County (TW); Jung-Yuan Tsai, Taoyuan County (TW); Wei-Huang Chiang, Taoyuan County (TW)

(72) Inventors: Yuan-Sheng Cheng, Taoyuan County (TW); Jung-Yuan Tsai, Taoyuan County (TW); Wei-Huang Chiang, Taoyuan County (TW)

(73) Assignee: HTC CORPORATION, Taoyuan County (TW)

(21) Appl. No.: 13/311,552

(22) Filed: Dec. 6, 2011

(51) Int. Cl. G06F 3/041; H05K 7/00

(52) U.S. Cl. 345/173; 361/679.01

(57) ABSTRACT

A handheld electronic device including a housing, a display panel and a backlight module is provided. The housing has a display opening and a transparent region located outside of the display opening. The display panel is disposed in the display opening. The backlight module is disposed in the housing. The backlight module has a light emitting region which is located under the display panel, adapted to provide a plane light source to the display panel. The light emitting region further extends to outside of the display panel so that a part of the plane light source is sent out the housing through the transparent region.

### BACKGROUND OF THE INVENTION

1. Field of the Invention

The invention relates to a handheld electronic device. More particularly, the invention relates to a handheld electronic device that uses a backlight module to provide display light.

2. Description of Related Art

A handheld electronic device is an electronic device which a user can carry around and operate on. The handheld electronic device is usually small and light for the user to carry conveniently. Common handheld electronic devices are, for example, a mobile phone, a multimedia player, a personal digital assistant (PDA), a handheld game console, a handheld global positioning system, or a notebook.

Using a mobile phone as an example, a plurality of keys are usually disposed in an area other than the display area of the display panel. Light emitting diodes are disposed below the keys, so as to provide light for the keys to be used. However, the light emitting diodes that provide light for the keys increase the production cost of the handheld electronic device. In addition, the light emitting diodes are located below the keys, which is disadvantageous towards the thinness of the handheld electronic device.

### SUMMARY OF THE INVENTION

The invention provides a handheld electronic device, wherein a light emitting region of a backlight module extends outside of the display panel, so as to reduce the light emitting components used by the handheld electronic device.

The invention provides a handheld electronic device including a housing, a display panel, and a backlight module. The housing includes a display opening and a transparent region located outside of the display opening. The display panel is disposed in the display opening. The backlight module is disposed in the housing. The backlight module has a light emitting region located below the display panel, and is adapted to provide a plane light source to the display panel. The light emitting region further extends to outside of the display panel so that a part of the plane light source is sent out the housing through the transparent region.

Based on the above, in the invention, the light emitting region of the backlight module extends to outside of the display panel, so that a part of the plane light source is sent out the housing through the transparent region. Thus, the light required by the transparent region can be directly provided by the backlight module. This reduces the amount of light emitting diodes required, which reduces the production cost of the handheld electronic device. In addition, since light emitting diodes are not disposed below the transparent region, the invention is advantageous towards the thinness of the handheld electronic device.

Several exemplary embodiments accompanied with figures are described in detail below to further describe the invention in details.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a schematic view illustrating a handheld electronic device according to an embodiment of the invention.

FIG. 2 is a schematic view of a display panel and a backlight module of FIG. 1.

FIG. 3 is a schematic cross-sectional view of a housing along line I-I′ of FIG. 1.

### DETAILED DESCRIPTION OF DISCLOSED EXEMPLARY EMBODIMENTS

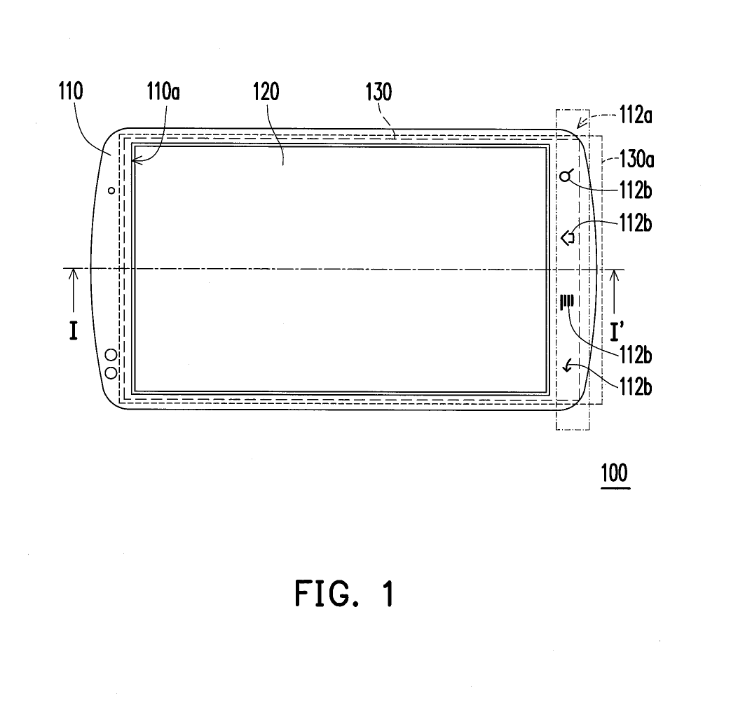

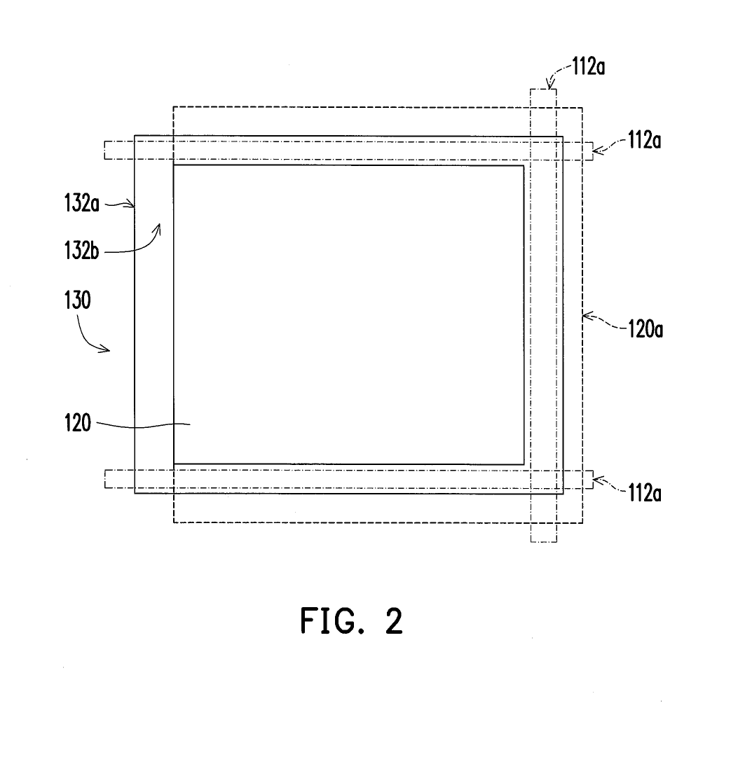

FIG. 1 is a schematic view illustrating a handheld electronic device according to an embodiment of the invention. FIG. 2 is a schematic view of a display panel and a backlight module of FIG. 1. Referring to FIG. 1 and FIG. 2, in the embodiment, the handheld electronic device 100 includes a housing 110, a display panel 120, and a backlight module 130. The housing 110 includes a display opening 110a and a transparent region 112a located outside of the display opening 110a. The display panel 120 is disposed in the display opening 110a. The backlight module 130 is disposed in the housing 110. The backlight module 130 has a light emitting region 130a located below the display panel 120, and is adapted to provide a plane light source to the display panel 120. The light emitting region 130a further extends outside of the display panel 120 so that a part of the plane light source is sent out the housing 110 through the transparent region 112a. Since the light emitting region 130a of the backlight module 130 extends to outside the display panel 120, the light required by the transparent region 112a can be directly provided by the backlight module 130. This reduces the amount of light emitting diodes required, which reduces the production cost of the handheld electronic device 100. In addition, since light emitting diodes are not disposed below the transparent region 112a, the thickness of the handheld electronic device 100 is reduced, which is advantageous towards the thinning of the handheld electronic device 100.

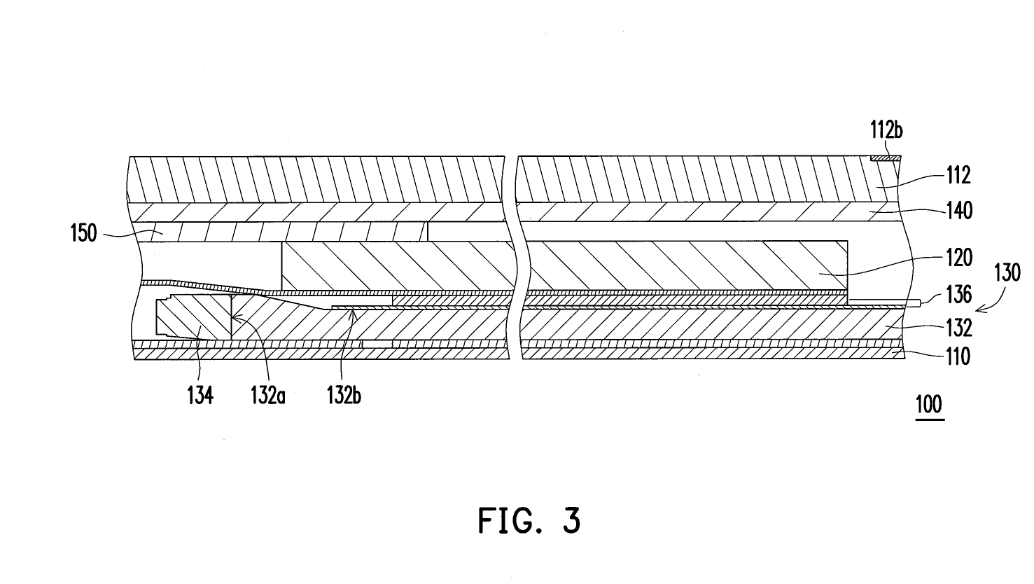

FIG. 3 is a schematic cross-sectional view of a housing along line I-I′ of FIG. 1. Referring to FIG. 1, FIG. 2, and FIG. 3, the housing 110 of the embodiment further includes a protective cover 112 that covers the display opening 110a and the display panel 120. The transparent region 112a is located on the protective cover 112. With this configuration, damage towards the display panel 120 when impacted can be avoided. In addition, the material of the protective cover 112 can be transparent material such as transparent glass or transparent plastic. This way, a portion of the plane light source of the backlight module 130 passes through the transparent region 112a. It should be noted that FIG. 3 is a cross-sectional view of FIG. 1, and in order for a clearer view of the figure, the proportions of the components in FIG. 3 have been modified.

The handheld electronic device 100 of the embodiment further includes a touch panel 140. The touch panel 140 is disposed on the display panel 120, and is located between the display panel 120 and the protective cover 112. In addition, a glue element 150 can be disposed between the display panel 120 and the touch panel 140. The glue element 150 is, for example, an adhesive tape, used to limit the movement of the touch panel 140 relative to the display panel 120. In addition, the touch panel 140 further extends to the transparent region 112a of the protective cover 112. The transparent region 112a includes a plurality of key icons 112b, and are located on the protective cover 112.

With this configuration, not only can the key icons 112b light up through the transparent region 112a, the key icons 112b also have a touch function by way of the touch panel 140.

The backlight module 130 of the embodiment includes a light guide plate 132 and a light emitting component 134. The light emitting component 134 is, for example, a light emitting diode. The light guide plate 132 includes an incident side 132a and a light exit surface 132b. The light guide plate 132 extends outside the display panel 120, so that the light exit surface 132b faces the display panel 120 and the transparent region 112a. The light emitting component 134 is disposed on the incident side 132a of the light guide plate 132. In detail, the light provided by the light emitting component 134 first enters the incident side 132a of the light guide plate 132. Then, after the light is transmitted in the light guide plate 132, it exits as a plane light source from the light exit surface 132b to the display panel 120 and is sent out the housing 110 through the transparent region 112a. Thus, the transparent region 112a can emit light.

In addition, the transparent region 112a can be disposed along a periphery of the display opening 110a. For example, the transparent region 112a of the embodiment is located on a side opposite to the incident side 132a of the light guide plate 132. The transparent region 112a can further be located on the two opposite sides of the incident side 132a of the light guide plate 132. In addition, in the embodiment, not only are the key icons 112b disposed on the transparent region 112a, tangible keys (not shown) can also be disposed within the boundaries of the transparent area 112a. The tangible keys can be lit up through the light emitted from the transparent area 112a. Thus, manufacturers can dispose the transparent region 112a along the display opening 110a of the housing 110 according to need.

The backlight module 130 of the embodiment further includes an optical film 136, disposed between the light guide plate 132 and the display panel 120. In addition, the optical film 136 covers the light exit surface 132b of the light guide plate 132, and extends to outside of the display panel 120. Furthermore, the optical film 136 of the embodiment includes a diffuser, a prism piece, or other optical films. With this configuration, the light from the backlight module 130 is more uniform and smoother.

To sum up, in the invention, the backlight module extends to outside of the display panel, so that the light provided by the light emitting region of the backlight module passes through the transparent region. Thus, the light required by the transparent region can be directly provided by the backlight module. This reduces the amount of light emitting diodes required, which reduces the production cost of the handheld electronic device. In addition, since light emitting diodes are not disposed below the transparent region, the invention is advantageous towards the thinness of the handheld electronic device. Furthermore, in the invention, the transparent region can be disposed along the periphery of the display opening of the housing. This way, there is more flexibility regarding the regions of the handheld electronic device that require light. In addition, the optical film of the backlight module can further cover the light guide plate, and extend to outside of the display panel. This allows the light from the backlight module to become more uniform and smoother.

It will be apparent to those skilled in the art that various modifications and variations can be made to the structure of the disclosure without departing from the scope or spirit of the invention. In view of the foregoing, it is intended that the disclosure cover modifications and variations of this invention provided they fall within the scope of the following claims and their equivalents.

What is claimed is:

1. A handheld electronic device, comprising:
a housing, having a display opening and a transparent region located outside of the display opening;
a display panel, disposed in the display opening; and
a backlight module, disposed in the housing, wherein the backlight module has a light emitting region located below the display panel, and is adapted to provide a plane light source to the display panel, and the light emitting region further extends outside of the display panel so that a part of the plane light source is sent out the housing through the transparent region.

2. The handheld electronic device as claimed in claim 1, wherein the housing includes a protective cover, covering the display opening and the display panel, and the transparent region is located on the protective cover.

3. The handheld electronic device as claimed in claim 2, further comprising:
a touch panel, disposed on the display panel, and located between the display panel and the protective cover.

4. The handheld electronic device as claimed in claim 3, wherein the touch panel further extends to the transparent region of the protective cover, and the transparent region includes a plurality of key icons.

5. The handheld electronic device as claimed in claim 1, wherein the transparent region is disposed along a periphery of the display opening.

6. The handheld electronic device as claimed in claim 1, wherein the backlight module comprises:
a light guide plate, having an incident side and a light exit surface, wherein the light guide plate extends to outside of the display panel, so that the light exit surface faces the display panel and the transparent region; and
a light emitting component, disposed on the incident side of the light guide plate.

7. The handheld electronic device as claimed in claim 6, wherein the transparent region is located on two opposite sides of the light guide plate other than the light incident side.

8. The handheld electronic device as claimed in claim 6, wherein the backlight module further comprises an optical film, disposed between the light guide plate and the display panel.

9. The handheld electronic device as claimed in claim 8, wherein the optical film covers the light exit surface of the light guide plate, and extends to outside of the display panel.

10. The handheld electronic device as claimed in claim 8, wherein the optical film comprises a diffuser.
